(19) United States
(12) Patent Application Publication
(10) Pub. No.: US 2025/0380540 A1
(43) Pub. Date: Dec. 11, 2025

(54) LIGHT EMITTING MODULE

(71) Applicant: SEOUL VIOSYS CO., LTD., Ansan-si (KR)

(72) Inventor: ChungHoon LEE, Ansan-si (KR)

(73) Assignee: SEOUL VIOSYS CO., LTD., Ansan-si (KR)

(21) Appl. No.: 19/229,086

(22) Filed: Jun. 5, 2025

Related U.S. Application Data
(60) Provisional application No. 63/658,201, filed on Jun. 10, 2024.

(51) Int. Cl. H10H 20/821; H10H 20/813; H10H 20/831; H10H 20/857

(52) U.S. Cl. CPC H10H 20/821; H10H 20/8131; H10H 20/831; H10H 20/857

(57) ABSTRACT

Disclosed is a light emitting module including a substrate and at least one light emitting unit disposed on a surface of the substrate. The light emitting module comprises a seating guide layer disposed on a surface of the substrate and having an open hole forming a seating region in which the light emitting unit is seated, wherein a width of the open hole in a first direction is greater than a length of a side of the light emitting unit in the first direction.

### TECHNICAL FIELD

The disclosed technology relates to a light emitting module including a light emitting unit.

### BACKGROUND ART

A light emitting diode (LED) is a light emitting device that emits light when electric current is applied thereto. In recent years, light emitting diodes have been used in various fields, such as display devices, vehicular lamps, and general lighting. Light emitting diodes have advantages of long lifespan, low power consumption, and fast response. With these advantages, light emitting diodes are rapidly replacing traditional light sources. For example, a display device using light emitting diodes may be obtained by individually growing structures of red (R), green (G), and blue (B) light emitting diodes (LEDs) on a final substrate.

Specifically, the light emitting diode is formed by growing epitaxial layers on a substrate and includes an N-type semiconductor layer, a P-type semiconductor layer, and an active layer interposed therebetween. An N-electrode pad is formed on the N-type semiconductor layer and a P-electrode pad is formed on the P-type semiconductor layer to allow the light emitting diode to be electrically connected to an external power source through the electrode pads. Here, electric current can flow from the P-electrode pad to the N-electrode pad through the semiconductor layers, and light generated by recombination of electrons and holes in the active layer can be emitted.

### DISCLOSURE

### Technical Problem

Embodiments of the disclosed technology may provide light emitting modules with improved performance and reliability.

Embodiments of the disclosed technology may provide light emitting modules that can facilitate alignment of a light emitting unit and can prevent movement of the light emitting unit.

Embodiments of the disclosed technology may provide light emitting modules that can miniaturize a light emitting unit.

Embodiments of the disclosed technology may provide light emitting modules with improved light extraction efficiency.

Embodiments of the disclosed technology may provide light emitting modules that can improve straightness of light emitted from a light emitting surface.

Embodiments of the disclosed technology may provide light emitting modules capable of preventing thermal deformation due to heat generation during operation.

Embodiments of the disclosed technology may provide light emitting modules that can prevent spreading of particles generated during operation.

Embodiments of the disclosed technology may provide light emitting modules capable of obtaining a wide light emitting region.

### Technical Solution

In accordance with one aspect of the disclosed technology, a light emitting module may include a substrate and at least one light emitting unit disposed on a surface of the substrate.

In one embodiment, the light emitting module may include a seating guide layer disposed on a surface of the substrate and having an open hole forming a seating region in which the light emitting unit is seated.

In one embodiment, a separation distance between the open hole and a side of the light emitting unit in the first direction may be less than or equal to 0.25 times a length of the side of the light emitting unit in the first direction.

In one embodiment, a length of the seating guide layer in the first direction may range from 2 times to 5 times the separation distance in the first direction.

In one embodiment, the light emitting unit may have a quadrangular shape having a length in the first direction and a length in a second direction perpendicular to the first direction in plan view and a diagonal length of the light emitting unit may be greater than the width of the open hole of the seating guide layer in the first direction.

In one embodiment, the light emitting unit may include a plurality of light emitting stacks vertically stacked on one above another and a vertical thickness of a light emitting stack adjacent to the substrate among the plurality of light emitting stacks may be greater than a thickness of the seating guide layer.

In one embodiment, the light emitting module further may include a bonding layer covering the seating guide layer and the seating region to secure the light emitting unit to the substrate, wherein a thickness of the bonding layer is less than a thickness of the seating guide layer.

In one embodiment, the light emitting module may further include: a protective layer disposed on the light emitting unit; an insulating layer disposed on the protective layer; and an electrode portion disposed on the insulating layer and connected to the light emitting unit through a first opening formed on the protective layer and a second opening formed on the insulating layer.

In one embodiment, the second opening may be disposed within the first opening.

In one embodiment, the light emitting unit includes first to third light emitting stacks vertically stacked in sequence on the substrate, and each of the first to third light emitting stacks may include a first conductivity type semiconductor layer, a second conductivity type semiconductor layer, and an active layer disposed between the first conductivity type semiconductor layer and the second conductivity type semiconductor layer.

In one embodiment, each of the first to third light emitting stacks may include a mesa etching region partially exposing the first conductivity type semiconductor layer and the first light emitting stack may be formed along one side thereof with a first exposed region in which the first conductivity type semiconductor layer is exposed by the mesa etching region.

In one embodiment, the first opening and the second opening in the first exposed region may have an elliptical shape having a long side length and a short side length, and a direction of the long side length may coincide with a longitudinal direction of the first exposed region.

In one embodiment, the first opening and the second opening in the second light emitting stack may have an elliptical shape having a long side length and a short side length, and a direction of the long side length may be perpendicular to the longitudinal direction of the first exposed region.

In one embodiment, the first opening in the first exposed region may have a larger area than the first opening in the second exposed region.

In one embodiment, the second opening in the first exposed region may have a larger area than the second opening in the second exposed region.

In one embodiment, a plurality of the light emitting units may be provided within the seating region.

In one embodiment, the light emitting unit may include a plurality of light emitting stacks vertically stacked one above another and an electrode portion disposed in grooves formed on side surfaces of the light emitting stacks.

In one embodiment, the light emitting unit may further include a connection layer disposed between adjacent light emitting stacks.

In one embodiment, the grooves may extend from an upper surface of the light emitting unit to a lower surface thereof.

In accordance with another aspect of the disclosed technology, a light emitting module includes a substrate and at least one light emitting unit disposed on a surface of the substrate, wherein the light emitting unit may include a plurality of light emitting stacks vertically stacked one above another, grooves formed on side surfaces of the plurality of light emitting stacks, a cover layer covering the grooves, and an electrode portion disposed within the grooves and connected to the light emitting stacks through openings formed on the cover layer.

In one embodiment, the light emitting unit may have a polygonal shape including an upper surface, a lower surface, and a plurality of side surfaces, and the electrode portion may include a plurality of electrodes vertically extending along the side surfaces of the light emitting unit.

In one embodiment, one of the plurality of electrodes may be a common electrode connected in common to the plurality of light emitting stacks, and the other electrodes excluding the common electrode may be individual electrodes connected to the plurality of light emitting stacks, respectively.

### Effects of the Invention

Embodiments of the disclosed technology may provide light emitting modules with improved performance and reliability.

Embodiments of the disclosed technology may provide light emitting modules that can facilitate alignment of a light emitting unit and prevent movement of the light emitting unit.

Embodiments of the disclosed technology may provide light emitting modules that can miniaturize a light emitting unit.

Embodiments of the disclosed technology may provide light emitting modules with improved light extraction efficiency.

Embodiments of the disclosed technology may provide light emitting modules that can improve straightness of light emitted from a light emitting surface.

Embodiments of the disclosed technology may provide light emitting modules capable of preventing thermal deformation due to heat generation during operation.

Embodiments of the disclosed technology may provide light emitting modules that can prevent spreading of particles generated during operation.

Embodiments of the disclosed technology may provide light emitting modules capable of obtaining a wide light emitting region.

### DESCRIPTION OF DRAWINGS

FIG. 1 is a cross-sectional view of a light emitting module according to a first embodiment.

FIG. 2 is a plan view of the light emitting module shown in FIG. 1.

FIG. 3 is a cross-sectional view of a light emitting module according to a second embodiment.

FIG. 4 is a plan view of the light emitting module shown in FIG. 3.

FIG. 5 is a top view of a modification of the light emitting module shown in FIG. 3.

FIG. 6 is a plan view of an example of a light emitting unit applicable to embodiments of the disclosed technology.

FIG. 7 is a cross-sectional view of the light emitting unit of FIG. 6 and a partially enlarged view thereof.

FIG. 8 is a cross-sectional view of a light emitting module according to a third embodiment.

FIG. 9 is a side view of a light emitting module according to a fourth embodiment.

FIG. 10 is a top view of the light emitting module shown in FIG. 9.

FIG. 11 is a top view of a modification of a light emitting unit shown in FIG. 9.

FIG. 12 is a side view of the light emitting unit shown in FIG. 11.

FIG. 13 to FIG. 17 are top views illustrating other modifications of the light emitting unit.

FIG. 18 is a perspective view of the light emitting module shown in FIG. 9.

FIG. 19 is a perspective view of a modification of the light emitting module according to the fourth embodiment.

FIG. 20 is a perspective view of another modification of the light emitting module according to the fourth embodiment.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Accordingly, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Accordingly, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Accordingly, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting module according to the disclosed technology will be described in detail with reference to the drawings.

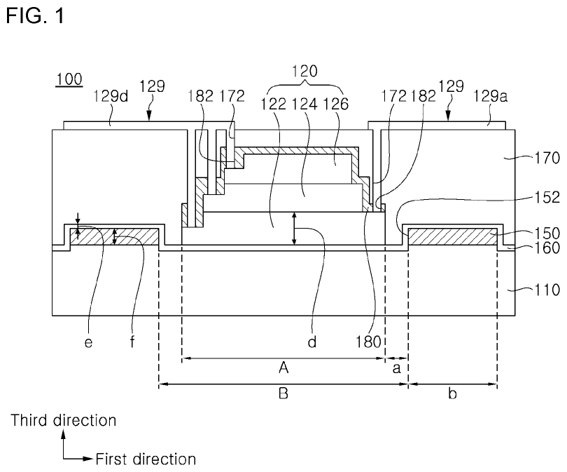

FIG. 1 is a side view of a light emitting module 100 according to a first embodiment. The light emitting module 100 may include a substrate 110 and at least one light emitting unit 120 on a surface of the substrate 110.

The substrate 110 is configured to allow the light emitting unit 120 to be mounted and supported on a surface thereof and is not limited to a particular type, such as a sapphire substrate, a circuit board, a light transmissive substrate, a glass substrate, a TFT substrate, a polymer substrate, a flexible substrate, a polyimide substrate, or others. The substrate 110 may have a larger area than the light emitting unit 120.

For example, the substrate 110 may include a printed circuit board (PCB). The PCB may include, for example, an FR4 PCB, which has good properties in terms of high strength, flame retardancy, chemical resistance, or others. Alternatively, the substrate 110 may be formed of at least one selected from among a poly (methyl methacrylate) (PMMA) resin, a polycarbonate (PC) resin, a cyclic olefin polymer (COP) resin, an acrylic resin, a polyethylene (PE) resin, an epoxy resin, and glass, all of which have light transmissive properties. Alternatively, the substrate 110 may be formed of a bendable material, such as PET, PVB, or the like. Alternatively, the substrate 110 may be a metal printed circuit board (Metal PCB) having good heat dissipation performance and good thermal conductivity. More specifically, the substrate 110 may be a PCB including Cu, Zn, Au, Ni, Al, Mg, Cd, Be, W, Mo, Si, Fe, or an alloy of at least one of these metals as a base metal. However, it should be understood that the disclosed technology is not limited thereto and various PCBs may be used depending on product characteristics.

The light emitting unit 120 may be a light emitting device disposed on a surface of the substrate 110 and emitting light. A plurality of light emitting units 120 may be arranged on a surface of the substrate 110 to be spaced apart from each other.

The light emitting unit 120 may have a length in a first direction and a length in a second direction perpendicular to the first direction in plan view, in which the first direction length and the second direction length may be less than or equal to 200 μm. Alternatively, the light emitting unit 120 may have an area of 40,000 μm2 or less in the first direction and the second direction. At least one light emitting unit 120 may have an EQE value of 80% or more at 10 mA/100 um2. At least one light emitting unit 120 may have a profile of increasing luminosity in the current range of 0 to 10 mA. The light emitting units 120 may have a drive voltage of 3 V or less. Accordingly, the light emitting units may reduce heat generation with high electrical efficiency in a small light emitting size.

Referring to FIG. 1, the light emitting unit 120 may be a light emitting diode including a plurality of light emitting stacks 122, 124, 126. However, it should be understood that the light emitting unit 120 of FIG. 1 is one example of the light emitting diode and the disclosed technology is not limited thereto.

The light emitting unit 120 may further include a growth substrate for growth of the plurality of light emitting stacks 122, 124, 126. The growth substrate may be a growth substrate for growing a gallium nitride semiconductor layer and may be, for example, a sapphire substrate, a silicon substrate, a SiC substrate, a spinel substrate, a Ga2O3 substrate, or the like. The growth substrate is not limited to a particular type and may be selected from any substrates so long as the substrate allows growth of nitride semiconductor layers thereon. The growth substrate may be removed after growth of the plurality of light emitting stacks 122, 124, 126.

Each of the light emitting stacks 122, 124, 126 may include a first conductivity type semiconductor layer, a second conductivity type semiconductor layer, and an active layer disposed between the first conductivity type semiconductor layer and the second conductivity type semiconductor layer.

The first conductivity type semiconductor layer may be a semiconductor layer grown on a surface of the growth substrate and may include a phosphide or nitride semiconductor, such as (Al, Ga, In)P or (Al, Ga, In)N. In addition, the first conductivity type semiconductor layer may be doped with at least one type of n-type dopant, such as Si, C, Ge, Sn, Te, Pb, or others. However, it should be understood that the disclosed technology is not limited thereto. Alternatively, the first conductivity type semiconductor layer may also be doped with a p-type dopant to become an opposite conductivity type. Furthermore, the first conductivity type semiconductor layer may include a single layer or multiple layers.

The active layer is a light emitting layer formed on a surface of the first conductivity type semiconductor layer, may include a phosphide or nitride semiconductor, such as (Al, Ga, In)P or (Al, Ga, In)N, and may be grown on the first conductivity type semiconductor layer through a technique, such as MOCVD, MBE, or HVPE. Further, the active layer may include a quantum well structure (QW) including at least two barrier layers and at least one well layer, and may further include a multi-quantum well structure (MQW) including a plurality of barrier layers and a plurality of well layers. The wavelength of light emitted from the active layer may be adjusted by controlling the composition ratio of materials constituting the well layers. In this case, the well layers may include the same element in common, for example, indium (In).

The second conductivity type semiconductor layer may be a semiconductor layer disposed on one side of the active layer. The second conductivity type semiconductor layer may include a phosphide or nitride semiconductor, such as (Al, Ga, In)P or (Al, Ga, In)N. The second conductivity type semiconductor layer may be doped to become a conductivity type opposite to the conductivity type of the first conductivity type semiconductor layer. For example, the second conductivity type semiconductor layer may be doped with p-type dopants, such as magnesium (Mg).

The light emitting device 120 may have a light emitting surface, through which light is emitted, on the first conductivity type semiconductor layer or the second conductivity type semiconductor layer. For example, light generated in the active layer may be emitted through the first conductivity type semiconductor layer or through the second conductivity type semiconductor layer. A surface of the first conductivity type semiconductor layer or a surface of the second conductivity type semiconductor layer may be formed with an uneven structure to improve light extraction efficiency.

Although FIG. 1 illustrates an example in which the light emitting device 120 includes a plurality of light emitting stacks 122, 124, 126 vertically stacked one above another, it should be understood that the disclosed technology is not limited thereto. For example, the light emitting device 120 may include one light emitting stack 122, 124, 126 or two light emitting stacks 122, 123, 124.

The plurality of light emitting stacks 122, 124, 126 may emit light with the same peak wavelength. Alternatively, at least one of the light emitting stacks 122, 124, 126 may emit light with a different peak wavelength than the other light emitting stacks 122, 124, 126.

For example, in FIG. 1, the light emitting device 120 may include a first light emitting stack 122, a second light emitting stack 124, and a third light emitting stack 126, which emit light with different peak wavelengths. The first through third light emitting stacks 122, 124, 126 may be vertically stacked on the substrate 110 in sequence. Light emitted from the third light emitting stack 126 may be emitted after passing through the second and first light emitting stacks 124, 122.

The first light emitting stack 122 may emit blue light, the second light emitting stack 124 may emit green light, and the third light emitting stack 126 may emit red light. This structure is provided by way of example and the disclosed technology is not limited thereto. Alternatively, the first light emitting stack 122 may emit red light, the second light emitting stack 124 may emit green light, and the third light emitting stack 126 may emit blue light. Alternatively, the first light emitting stack 122 may emit green light, the second light emitting stack 124 may emit blue light, and the third light emitting stack 126 may emit red light.

That is, the light emitting stacks 122, 124, 126 configured to emit red, green and blue light may be vertically stacked in the light emitting unit 120. Alternatively, the light emitting stacks 122, 124, 126 configured to emit the same color may be vertically stacked therein.

Connection layers may be disposed between the first and third light emitting stacks 122, 124, 126 for bonding therebetween. Specifically, a first connection layer may be disposed between the first light emitting stack 122 and the second light emitting stack 124. A second connection layer may be disposed between the second light emitting stack 124 and the second light emitting stack 126.

Further, each of the light emitting stacks 122, 124, 126 may include a mesa etching region that partially exposes the first conductivity type semiconductor layer. The mesa etching region may form an exposed region in which the first conductivity type semiconductor layer of each of the light emitting stacks 122, 124, 126 is partially exposed.

The first to third light emitting stacks 122, 124, 126 may form first to third exposed regions, respectively.

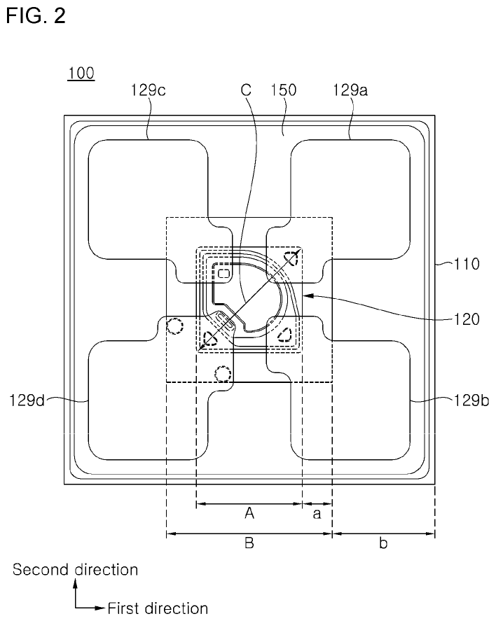

Referring to FIG. 1 and FIG. 2, the light emitting unit 120 may include an electrode portion 129 connected to the light emitting stacks 122, 124, 126. The electrode portion 129 may include a plurality of electrodes 129a, 129b, 129c, 129d.

One of the electrodes 129a, 129b, 129c, 129d may be a common electrode 129d connected in common to the plurality of light emitting stacks 122, 124, 126, and the remaining electrodes may be individual electrodes 129a, 129b, 129c connected to the plurality of light emitting stacks 122, 124, 126, respectively. As the light emitting unit 120 includes the first to third light emitting stacks 122, 124, 126, the light emitting unit 120 may include first to third individual electrodes 129a, 129b, 129c connected to the first to third light emitting stacks 122, 124, 126, respectively.

The common electrode 129d may be connected to the first to third exposed regions of the first to third light emitting stacks 122, 124, 126. By being connected to the first to third exposed regions, the common electrode 129d may serve as a common electrode electrically connected to the same conductive semiconductor layer of either the first conductivity type semiconductor layer or the second conductivity type semiconductor layer.

The individual electrode 129a, 129b or 129c may be connected to the first conductivity type semiconductor layer or the second conductivity type semiconductor layer of each of the light emitting stacks 122, 124, 126. The conductive semiconductor layers electrically connected to the individual electrodes 129a, 129b, 129c may have different polarities than the conductive semiconductor layers to which the common electrode 129d is electrically connected.

On the other hand, the light emitting module 100 may further include a seating guide layer 150 disposed on a surface of the substrate 110.

The seating guide layer 150 may include an open hole 152 that defines a seating region in which the light emitting unit 120 is seated. The open hole 152 may be an opening that partially exposes the substrate 110.

The seating guide layer 150 may be an insulating layer formed of various materials, for example, SiO2. The seating guide layer 150 may have various thicknesses f depending on design. For example, the seating guide layer 150 may have a thickness of 100 nm.

The open hole 152 may have various planar shapes, for example, a quadrangular shape with a first direction length and a second direction length perpendicular thereto in plan view.

A width B of the open hole 152 in the first direction may be greater than a length A of a side of the light emitting unit 120 in the first direction.

Referring to FIG. 2, the light emitting unit 120 may have a quadrangular shape with a first direction length and a second direction length perpendicular to the first direction in plan view, in which a diagonal length C of the light emitting unit 120 may be determined. The diagonal length C of the light emitting unit 120 may be greater than the width B of the open hole 152 of the seating guide layer 150 in the first direction. Accordingly, when the light emitting unit 120 is seated on the substrate 110, it is possible to prevent corners of the seating guide layer 150 from being damaged by the light emitting unit 120.

A separation distance a between the open hole 152 and the side of the light emitting unit 120 in the first direction may be less than or equal to 0.25 times of a length A of the side of the light emitting unit 120. Accordingly, when the light emitting units 120 are disposed on the substrate 110, it is possible to prevent the light emitting units 120 from changing in viewing angle through excessive rotation thereof.

In the first direction, the seating guide layer 150 may have a length b ranging from 2 times to 5 times the separation distance a. As a result, the effect of separating the light emitting units 120 by the seating guide layer 150 may be improved. The seating guide layer 150 may be provided with a plurality of open holes 150 and the length b of the seating guide layer 150 may correspond to a separation distance between adjacent open holes 150.

A vertical thickness of the light emitting unit 120 may be greater than the thickness f of the seating guide layer 150. The thickness f of the seating guide layer 150 may be set by taking into account the thickness of the light emitting unit 120.

When the light emitting unit 120 includes a plurality of light emitting stacks 122, 124, 126, a vertical thickness d of the light emitting stack adjacent to the substrate 110, that is, the first light emitting stack 122, may be greater than the thickness f of the seating guide layer 150. The vertical thickness d of the first light emitting stack 122 may range from 2 μm to 8 μm. Accordingly, light generated from the first light emitting stack 122 may be prevented from being excessively absorbed by the seating guide layer 150.

The thickness f of the seating guide layer 150 may range from 1% to 10% of the vertical thickness d of the first light emitting stack 122.

Although FIG. 1 and FIG. 2 illustrate an example of one light emitting unit 120 disposed within a single seating region, it should be understood that the disclosed technology is not limited thereto.

In addition, the light emitting module 100 may further include a bonding layer 160 disposed on the seating guide layer 150 to secure the light emitting unit 120 to a surface of the substrate 110. As the light emitting unit 120 is disposed on the bonding layer 160 and secured thereto, the light emitting unit 120 is prevented from moving within the seating region. The bonding layer 160 may have various configurations and may be formed of, for example, a polymeric material, such as polyimide or SiO2, so long as the light emitting unit 120 may be securely bonded to the bonding layer. A region of the substrate 110 adjoining the seating guide layer 150 may protrude upwards to form a step. The light emitting unit 120 may be surrounded by the step of the substrate 110. Accordingly, the height of the seating guide layer 150 may be increased by the step of the substrate 110.

In another embodiment, an upper surface of the region of the substrate 110 adjoining the seating guide layer 150 may be coplanar with an upper surface of the seating region in which the light emitting unit 120 is disposed. Accordingly, the position of the seating guide layer 150 may be easily moved or redesigned to facilitate adjustment of the pitch of pixels.

A thickness e of the bonding layer 160 may be thinner than the thickness f of the seating guide layer 150. For example, the thickness f of the seating guide layer 150 may range from 7 times to 30 times the thickness e of the bonding layer 160. Accordingly, the bonding layer 160 may be continuously formed even in the separation region between the open hole 152 and the side of the light emitting unit 120.

In addition, the light emitting module 100 may further include an insulating layer 170 disposed on the light emitting unit 120. The electrode portion 129 may be disposed on the insulating layer 170 and may be connected to the light emitting unit 120 through a second opening 172 formed in the insulating layer 170. Alternatively, in consideration of a light emission direction, the electrode portion 129 may be disposed between the insulating layer 170 and the substrate 110 and covered by the insulating layer 170.

The insulating layer 170 may cover the bonding layer 160 and the light emitting unit 120, and may include an organic or inorganic insulating material, for example, polyimide, SiO2, SiNx, Al2O3, Si, C, or others.

The light emitting module 100 may further include a protective layer 180 under the insulating layer 170. The protective layer 180 may cover the light emitting unit 120 and may be a distributed Bragg reflector having a multilayer structure. In consideration of the light emission direction, the protective layer 180 may be disposed between the light emitting unit 120 and the substrate 110.

The protective layer 180 may include a first opening 182 and the electrode 129 may be connected to the light emitting unit 120 through the first opening 182.

The electrode 129 is connected to the light emitting unit 120 through the first opening 182 and the second opening 172, which may be disposed within the first opening 182.

The first opening 182 may have a larger area than the second opening 172.

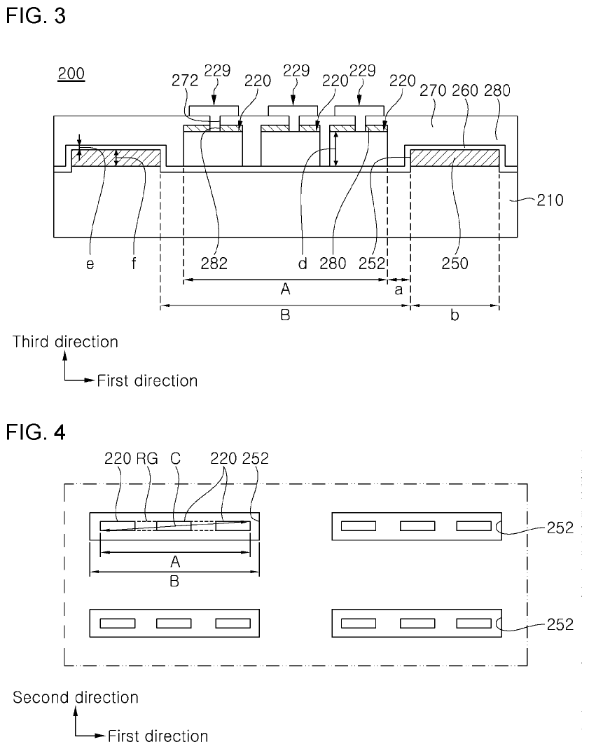

FIG. 3 illustrates a light emitting module 200 according to a second embodiment. The light emitting module 200 according to the second embodiment may have a similar configuration to the light emitting module 200 according to the first embodiment except that a plurality of light emitting units 220 is disposed within one seating region. The following description will focus on different features of the light emitting module 200 according to the second embodiment from the light emitting module 100 according to the first embodiment.

The light emitting unit 220 may have various configurations and may include one or two light emitting stacks unlike the light emitting unit shown in FIG. 1 and FIG. 2. For example, three light emitting units 220 may be disposed in one seating region and each of the light emitting units 220 may include one light emitting stack configured to emit blue, green, and red light. The three light emitting units 220 may constitute one pixel. Protective layers 280 covering the light emitting units 220 may be spaced apart from each other so as correspond to the light emitting units 220, respectively.

An electrode portion 229 may be electrically connected to each of the light emitting units 220. In this embodiment, the electrode portion 229 may be disposed to face a substrate 210 with reference to the light emitting units 220. A space between the light emitting units 220 and a space between a seating guide layer 250 and the light emitting units 220 may be filled with an insulating layer 270. Accordingly, the light emitting units 220 may be prevented from being moved or rotated in the seating region.

In another embodiment, although not shown in the drawings, the electrode portion 229 may be disposed between the light emitting units 220 and the substrate 210. Accordingly, the insulating layer 270 may cover the top of the light emitting units 220 and may extend between the seating guide layer 250 and the light emitting units 220. Each of the light emitting units 220 may have a square or quadrangular shape having a long side length and a short side length. For example, as shown in FIG. 4, the light emitting units 220 disposed within one seating region may be arranged in a long side direction (first direction) there. A width B of the open hole 252 in an arrangement direction of the light emitting units (first direction) may be greater than a first direction length A of an arrangement region RG in which the light emitting units 220 are arranged. A diagonal length C of the arrangement region RG may be greater than the width B of the open hole 252 in the first direction. Accordingly, the light emitting units 220 may be disposed such that the long side surfaces of the light emitting units 220 do not face each other, thereby effectively preventing color mixing. Accordingly, it is possible to prevent the corners of the seating guide layer 250 from being damaged by the light emitting units 220 when the light emitting units 220 are seated on the substrate 210.

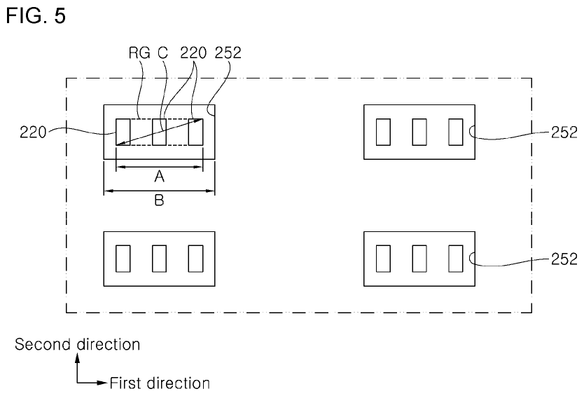

Alternatively, as shown in FIG. 5, the light emitting units 220 disposed within a single seating region may be arranged in a short side direction (first direction) thereof. The width B of the open hole 252 in the arrangement direction of the light emitting units (first direction) may be greater than the first direction length A of the arrangement region RG in which the light emitting units 220 are arranged. The diagonal length C of the arrangement region RG may be greater than the width B of the open hole 252 in the first direction. Accordingly, it is possible to prevent the corners of the seating guide layer 250 from being damaged by the light emitting units 220 when the light emitting units 220 are seated on the substrate 210. Furthermore, the contrast of the light emitting device may be increased by securing a wide distance between the open holes 252.

The separation distance a between the open hole 252 and the side of the light emitting unit 220 in the first direction may be less than or equal to 0.25 times of the length A of the side of the arrangement region RG of the light emitting units 120. Accordingly, when the light emitting units 220 are disposed on the substrate 210, it is possible to prevent the light emitting units 220 from changing in viewing angle through excessive rotation thereof.

In the first direction, the length b of the seating guide layer 250 may range from 2 times to 5 times the separation distance a. Accordingly, the effect of separating the light emitting units 220 by the seating guide layer 250 may be improved. The seating guide layer 250 may be provided with a plurality of open holes 250 and the length b of the seating guide layer 250 may correspond to a separation distance between adjacent open holes 250.

A vertical thickness d of the light emitting units 220 may be greater than the thickness f of the seating guide layer 250. The thickness f of the seating guide layer 250 may be set by taking into account the thickness d of the light emitting units 220. The vertical thickness d of the light emitting units 220 may range from 2 μm to 8 μm. For example, the thickness f of the seating guide layer 250 may range from 1% to 10% of the vertical thickness d of the light emitting units 220. Accordingly, light generated from the light emitting units 220 may be prevented from being excessively absorbed by the seating guide layer 250.

When the light emitting unit 220 includes a plurality of light emitting stacks, the thickness of the light emitting stack adjacent to the substrate 210 may be greater than the thickness f of the seating guide layer 250.

A thickness e of the bonding layer 260 may be thinner than the thickness f of the seating guide layer 250. For example, the thickness f of the seating guide layer 250 may range from 7 times to 30 times the thickness e of the bonding layer 260. Accordingly, the bonding layer 260 may be continuously formed even in the separation region between the open hole 252 and the side of the light emitting unit 220.

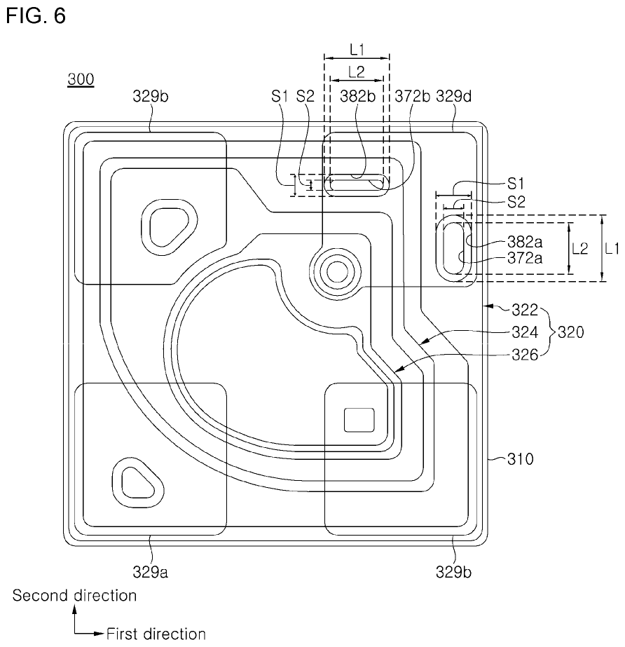

Next, FIG. 6 is a plan view of an exemplary light emitting unit 300 applicable to the embodiments of the disclosed technology, showing the shape and arrangement of first and second openings 382, 372 of a protective layer 380 and an insulating layer 370. In the light emitting unit 300 according to the exemplary embodiment, the shape and arrangement of the first and second openings 382, 372 of the protective layer 380 and the insulating layer 370 may be similarly applied to the light emitting modules 100, 200 according to the first and second embodiments. The protective layer 380 may be a DBR layer.

Specifically, referring to FIG. 6, the light emitting unit 300 may include first to third light emitting stacks 322, 324, 326. A first connection layer 323 may be disposed between the first light emitting stack 322 and the second light emitting stack 324 and a second connection layer 325 may be disposed between the second light emitting stack 324 and the third light emitting stack 326.

A first exposed region of the first light emitting stack 322 adjacent to the substrate 310 may extend along one side of the light emitting unit 300. For example, the first exposed region may extend along the side of the light emitting unit 300 in the second direction.

At least one of the first and second openings 382, 372 of the protective layer 380 and the insulating layer 370 may have an elliptical shape having long side lengths L1, L2 and short side lengths S1, S2. The light emitting unit 300 may be connected to a common electrode 329d through the first and second openings 382, 372 having the elliptical shape.

Here, the directions of the long side lengths L1, L2 of the first opening 382a of the protective layer 380 and the second opening 372a of the insulating layer 370 disposed in the first exposed region of the first light emitting stack 322 may correspond to the longitudinal direction (second direction) of the first exposed region. This structure may secure a wide light emitting region of the first light emitting stack 322 while increasing the amount of emitted light.

A second exposed region of the second light emitting stack 324 disposed on the first light emitting stack 322 may extend in the first direction perpendicular to the second direction.

Here, the directions of the long side lengths L1, L2 of the first opening 382b of the protective layer 380 and the second opening 372b of the insulating layer 370 disposed in the second exposed region may be perpendicular to the longitudinal direction (second direction) of the first exposed region. This structure allows the first and second openings 382a, 372a disposed in the first exposed region and the first and second openings 382a, 372a disposed in the second exposed region to be spaced farther apart from each other.

The first opening 382a in the first exposed region may have a larger area than the first opening 382b in the second exposed region. Similarly, the second opening 372a in the first exposed region may have a larger area than the second opening 372b in the second exposed region. As the first to third light emitting stacks 322, 324, 326 are vertically stacked in sequence, a light emitting area of the first light emitting stack 322 is formed to be relatively larger than a light emitting region of the second light emitting stack 324, and the first opening 382a and the second opening 372a in the first exposed region are formed to have larger areas than those in the second exposed region, thereby providing a larger contact area with the common electrode 329d in the first exposed region. Accordingly, it is possible to reduce resistance due to difference in light emitting area of the light emitting stacks 322, 324, 326.

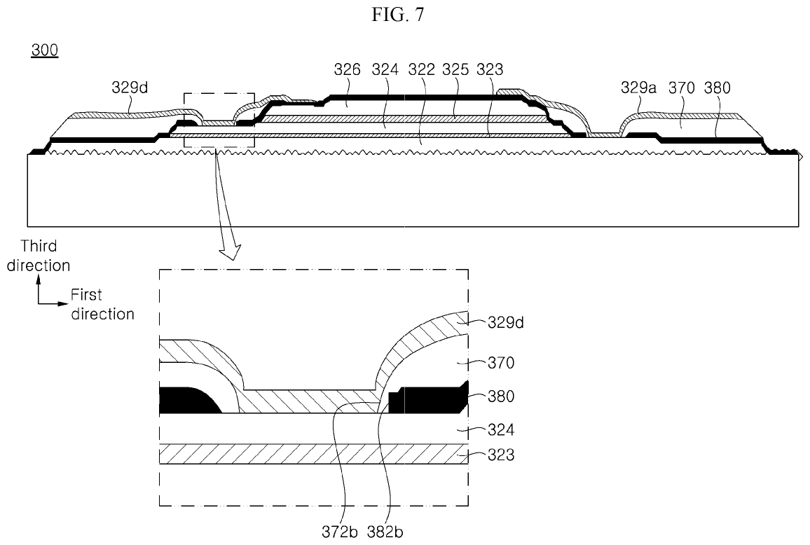

On the other hand, FIG. 7 is a partially enlarged view of the cross-section shown in FIG. 6, in which the second opening 372b of the insulating layer 370 may be disposed within the first opening 382b of the protective layer 380. The second opening 372b of the insulating layer 370 may be formed in a smaller size than the first opening 382a of the protective layer 380. Accordingly, a side of the first opening 382a may be spaced apart from the common electrode 329d. As a result, a distance from the second opening 372b of the insulating layer 370 to an upper surface of the insulating layer 370 may be increased and a gentle slope may be formed from the second opening 372b of the insulating layer 370 to the upper surface of the insulating layer 370. Accordingly, the common electrode 329d disposed thereon may be stably continuously formed due to a steep slope and stable electrical connection may be formed.

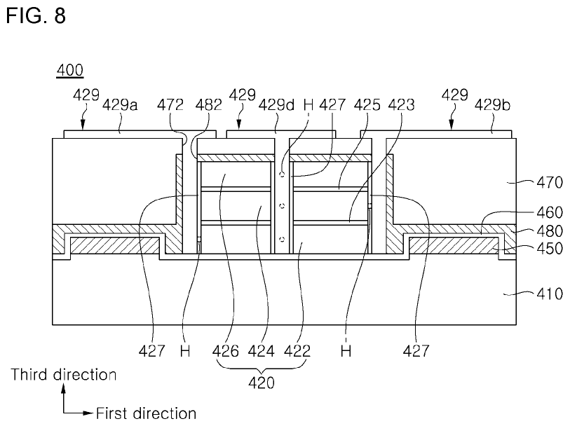

Next, FIG. 8 shows a light emitting module 400 according to a third embodiment. The light emitting module 400 according to this embodiment may have the same or similar configuration to the light emitting modules 100, 200 according to the first and second embodiments except for a light emitting unit 420, and repeated description of the same or similar components will be omitted.

The light emitting unit 420 may include first to third light emitting stacks 422, 424, 426 vertically stacked in sequence on a substrate 410. The light emitting unit 420 may further include connection layers 423, 425 disposed between the light emitting stacks 422, 424, 426. The light emitting unit 420 may include a first connection layer 423 disposed between the first light emitting stack 422 and the second light emitting stack 424, and a second connection layer 425 disposed between the second light emitting stack 424 and the third light emitting stack 426.

The light emitting unit 420 may include a cover layer 427 surrounding the light emitting stacks 422, 424, 426. The cover layer 427 may be an insulating layer formed of an insulating material.

The cover layer 427 surrounds the light emitting stacks 422, 424, 426 and is disposed between the light emitting stacks 422, 424, 426 and the electrode portion 429. The cover layer 427 may include openings H for connection between a plurality of electrodes 429a, 429b, 429c, 429d and a plurality of light emitting stacks 422, 424, 426. The openings H are formed to partially expose the light emitting stacks 422, 424, 426 and the plurality of electrodes 429a, 429b, 429c, 429d may be electrically connected to the plurality of light emitting stacks 422, 424, 426 through the openings H of the cover layer 427.

On the other hand, the light emitting unit 420 may be formed in a polygonal column shape including an upper surface, a lower surface, and a plurality of side surfaces, with a plurality of light emitting stacks 422, 424, 426 stacked one above another. Here, a lower surface of the light emitting unit 420 may be defined as a surface thereof opposite a surface of the substrate 410 and an upper surface thereof may be defined as a surface thereof opposite the lower side thereof.

The side surfaces of the light emitting unit 420 refer to faces connecting the upper and lower surfaces to each other, and may be perpendicular to a surface of the substrate 410 or may be inclined thereto.

For example, the light emitting unit 420 may have a quadrangular column shape having a quadrangular shape in plan view. However, it should be understood that this is provided by way of example and the disclosed technology is not limited thereto. The light emitting unit 420 may have four side surfaces and four corners in which adjacent side surfaces meet. The corners may be regions in which two side surfaces meet and may be included in the side surfaces.

Each of the side surfaces of the light emitting unit 420 may be formed with at least one groove G. The groove G may refer to a hollow space indented into the side surface of the light emitting unit 420. The groove G may have an inner surface IS that defines the hollow space of the groove G.

The grooves G may be vertically formed along the side surfaces of the plurality of light emitting stacks 422, 424, 426. Here, the vertical direction may correspond to a stacking direction of the light emitting stacks 422, 424, 426. The grooves G may extend from the upper surface of the light emitting unit 420 to the lower surface thereof. That is, the grooves G may be formed on the side surfaces of the light emitting unit 420 to pass through the upper and lower surfaces thereof. The grooves G may extend from the first light emitting stack 422 and pass through the first connection layer 423. In addition, the grooves G may extend from the first connection layer 423 and pass through the second light emitting stack 424. The grooves G may extend from the second light emitting stack 424 and pass through the second connection layer 425. The grooves G may extend from the second connection layer 425 and pass through the third light emitting stack 426. The grooves G may extend from the first light emitting stack 422 to the third light emitting stack 426.

For example, the groove G may be formed on each side surface of the light emitting unit 420. As the light emitting unit 420 has four side surfaces, the light emitting unit 420 may include four grooves G formed on the side surfaces, respectively. However, it should be understood that the disclosed technology is not limited thereto and the grooves G may also be formed on the corners in which adjacent side surfaces of the light emitting unit 420 meet.

An electrode portion 429 may be disposed in the groove G. Specifically, the electrode portion 429 of the light emitting unit 420 may be disposed in the groove G. In one groove G, one electrode 429a, 429b, 429c or 429d may be disposed corresponding thereto.

Accordingly, the number of grooves G formed on the light emitting unit 520 may be the same as the number of electrodes 429a, 429b, 429c, 429d of the light emitting unit 420. In FIG. 8, as the light emitting unit 420 includes three light emitting stacks 422, 424, 426, the light emitting unit 420 is provided with four electrodes 429a, 429b, 429c, 429d and may be formed with four grooves G corresponding to the electrodes 429a, 429b, 429c, 429d, respectively.

As the electrodes 429a, 429b, 429c, 429d are disposed in the corresponding grooves G, the electrodes 429a, 429b, 429c, 429d may also vertically extend along the side surfaces of the light emitting stacks 422, 424, 426.

When the grooves G are formed in corner regions of the light emitting stacks 422, 424, 426, the electrodes 429a, 429b, 429c, 429d may also vertically extend along the corners in which adjacent side surfaces of the light emitting unit meet.

As the electrodes 429a, 429b, 429c, 429d are disposed within the grooves G, the openings H of the cover layer 427 may be formed within the grooves G.

Inner circumferential surfaces of the grooves G may be covered by the cover layer 427, and the cover layer 427 may be covered by the electrodes 429a, 429b, 429c, 429d. The cover layer 427 may include the openings H that at least partially expose the light emitting stacks 422, 424, 426 on the inner circumferential surfaces of the grooves G. The cover layer 427 may extend to outer side surfaces of the light emitting stacks 422, 424, 426 beyond the grooves G. In addition, the cover layer 427 may cover an interface between the light emitting stacks 422, 424, 426 and the connection layers 423, 425.

Since the electrodes 429a, 429b, 429c, 429d vertically extend along the grooves G, the common electrode 429d may be connected to each of the light emitting stacks 422, 424, 426 through a plurality of openings H formed at different heights. The plurality of openings H corresponding to the common electrode 429d may be vertically disposed. That is, the cover layer 427 may be formed with the plurality of openings H at different heights.

Each of the electrodes 429a, 429b, 429c, 429d may have a different length. Each of the electrodes 429a, 429b, 429c, 429d may also have a different width-to-height ratio.

Referring to FIG. 8, each of the electrodes 429a, 429b, 429c, 429d may be exposed through a second opening 472 of the insulating layer 470. The second opening 472 of the insulating layer 470 may be disposed within the first opening 482 of the protective layer 480.

Although FIG. 8 shows an example in which the electrodes 429a, 429b, 429c, 429d are disposed within the corresponding grooves G, it should be understood that the disclosed technology is not limited thereto. The electrodes 429a, 429b, 429c, 429d may extend from the grooves G to peripheral regions thereof.

The grooves G may have various widths and depths. The widths and depths of the grooves G may be substantially uniform depending on the distance from a surface of the substrate 410. Here, the width of each of the grooves G may refer to a length parallel to the side surface on which the groove G is formed and the depth thereof may refer to a length perpendicular to the side surface on which the groove G is formed.

Such a shape of the grooves G is provided by way of example and the shapes and sizes of the grooves G may be varied depending on design.

By way of example, the width of the groove G may be varied depending on the distance from a surface of the substrate 410. The width of the groove G may increase with increasing distance from the a surface of the substrate 410.

Alternatively, the depth of the groove G may be varied depending on the distance from a surface of the substrate 410. The depth of the groove G may increase with increasing distance from the a surface of the substrate 410.

In addition, the depression areas of the grooves G refer to cross-sectional areas of regions formed by the grooves G and may be varied depending on the distance from a surface of the substrate 410. The depression areas of the grooves G may increase with increasing distance from the a surface of the substrate 410.

At least a portion of the inner circumferential surface of the groove G may be a curved surface.

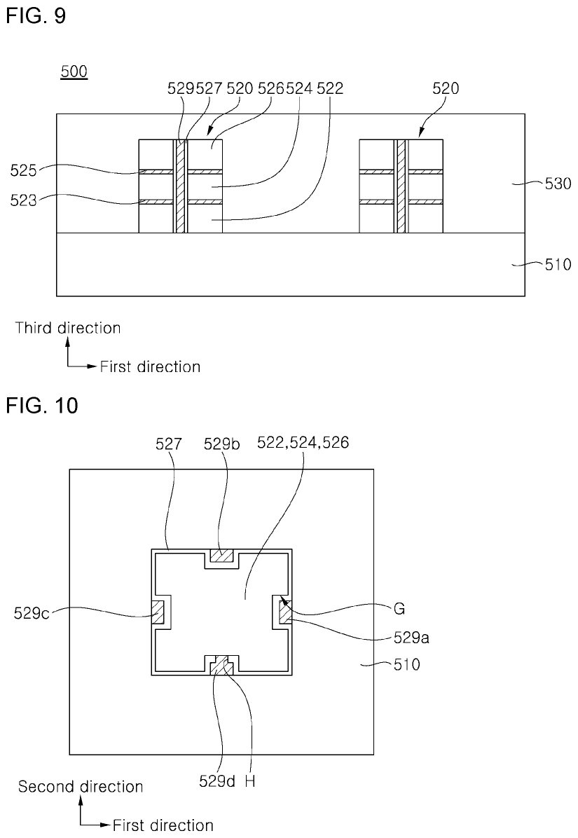

FIG. 9 is a side view of a light emitting module 500 according to a fourth embodiment, in which the light emitting module 500 may include a substrate 510 and light emitting units 520 disposed on a surface of the substrate 510. In the light emitting module 500 according to the fourth embodiment, the substrate 510 may have the same or similar configuration to the substrates 110, 210, 410 of the light emitting modules 100, 200, 400 according to the first through third embodiments. The light emitting unit 520 may have the same or similar configuration to the light emitting unit 420 of the light emitting module 400 according to the third embodiment. The light emitting module 500 may further include a molding member 530.

The light emitting module 500 may include the substrate 510 and the light emitting units 520 disposed on a surface of the substrate 510. The light emitting unit 520 may have the same or similar configuration to the light emitting unit 420 shown in FIG. 8 and repeated description of the same or similar configuration will be omitted.

An electrode portion 529 may be electrically connected to the substrate 510 by a conductive material disposed between the light emitting unit 520 and the substrate 510. The conductive material may extend to side surfaces of the first light emitting stack 522 to partially cover the side surfaces of the first light emitting stack 522.

Referring to FIG. 9, the light emitting module 500 may further include the molding member 530 that covers a surface of the substrate 510 and the light emitting units 520. The molding member 530 may cover the side surfaces of the light emitting unit 520 or at least a region of an upper surface thereof and may transmit at least a fraction of light emitted from the light emitting unit 520. The molding member 530 may at least partially cover the light emitting unit 520 to protect the light emitting unit 520 from moisture and external impact. The molding member 530 may further include fillers, such as silica, TiO₂, alumina, or others. The molding member 530 may be formed to cover both the upper surface and the side surfaces of the light emitting unit 520. The molding member 530 may be formed as a molding layer having light transmissive properties.

FIG. 10 is a top view of the light emitting unit 520 shown in FIG. 9, showing grooves G formed on side surfaces of light emitting stacks 522, 524, 526, a cover layer 527 covering the light emitting stacks 522, 524, 526, and electrodes 529a, 529b, 529c, 529d disposed within the grooves G and connected to the light emitting stacks 522, 524, 526 through openings H formed on the cover layer 527.

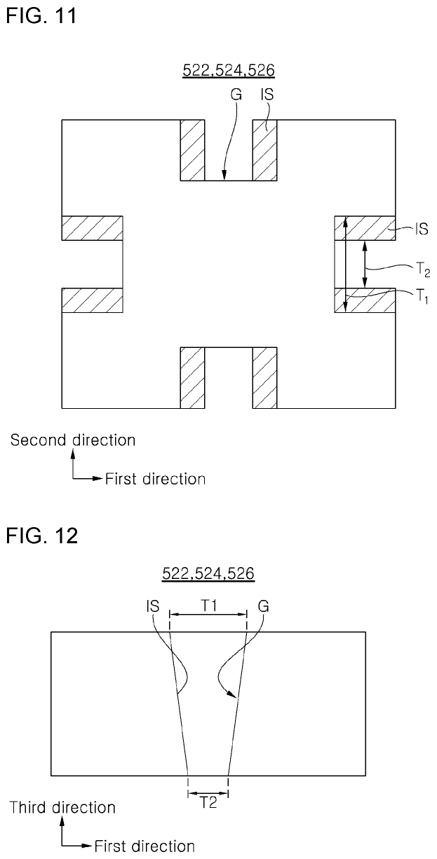

The light emitting unit 520 of the light emitting module 500 may be modified in various ways. First, FIG. 11 and FIG. 12 are a plan view and a side view of light emitting stacks 522, 524, 526 of another exemplary light emitting unit 520, respectively. Referring to FIG. 11 and FIG. 12, the grooves G on the side surfaces of the light emitting stacks 522, 524, 526 may have variable widths T1, T2 depending on the distance from a surface of the substrate 510. Here, the widths T1, T2 of the grooves G may refer to a length parallel to the side surfaces of the light emitting stacks 522, 524, 526 and may correspond to a distance between inner surfaces IS of the groove G, which face each other.

Referring to FIG. 12, the grooves G may have a minimum width T2 on the lower surface of the light emitting stacks 522, 524, 526 and a maximum width T1 on the upper surface thereof.

As a result, since the depression areas of the grooves G increase with increasing distance from the substrate 510, the light emitting units 520 may be more stably supported on the substrate 510.

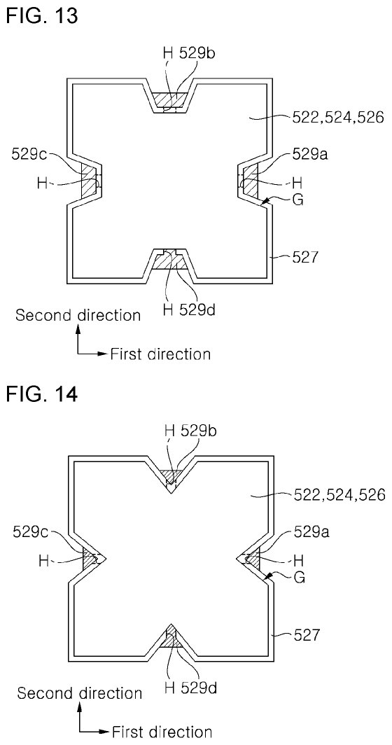

Next, FIG. 13 is a plan view of light emitting stacks 522, 524, 526 of another exemplary light emitting unit 520. Referring to FIG. 13, the grooves G formed on the side surfaces of the light emitting stacks 522, 524, 526 may have a trapezoidal cross-section having a width that decreases with increasing depth.

The groove G may be formed on each of the side surfaces of the light emitting stack 522, 524, 526 and a corresponding electrode 529a, 529b, 529c or 529d may be disposed within the groove G. One of the electrodes 529a, 529b, 529c, 529d may be a common electrode 529d connected to all of the plurality of light emitting stacks 522, 524, 526.

Next, FIG. 14 is a plan view of light emitting stacks 522, 524, 526 of another exemplary light emitting unit 520. Referring to FIG. 14, the grooves G formed on the side surfaces of the light emitting stacks 522, 524, 526 may have a triangular cross-section having a width that decreases with increasing depth.

The groove G may be formed on each of the side surfaces of the light emitting stack 522, 524, 526 and a corresponding electrode 529a, 529b, 529c or 529d may be disposed within the groove G. One of the electrodes 529a, 529b, 529c, 529d may be a common electrode 529d connected to all of the plurality of light emitting stacks 522, 524, 526.

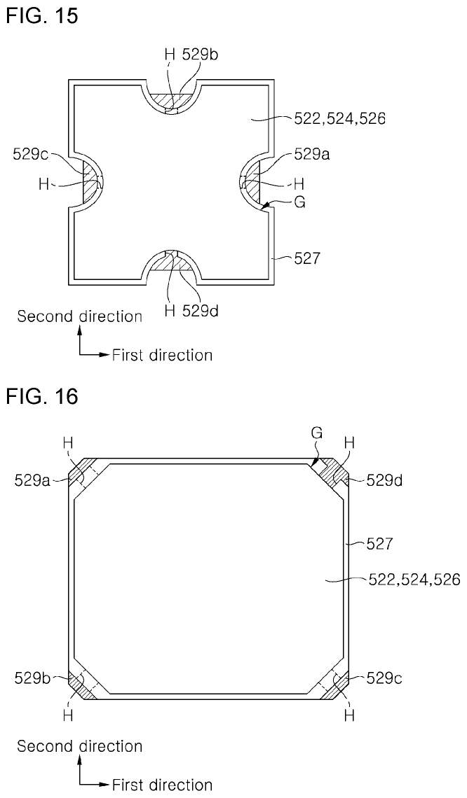

Next, FIG. 15 is a plan view of light emitting stacks 522, 524, 526 of another exemplary light emitting unit 520. Referring to FIG. 15, the grooves G formed on the side surfaces of the light emitting stacks 522, 524, 526 may have a semicircular cross-section.

The groove G may be formed on each of the side surfaces of the light emitting stack 522, 524, 526 and a corresponding electrode 529a, 529b, 529c or 529d may be disposed within the groove G. One of the electrodes 529a, 529b, 529c, 529d may be a common electrode 529d connected to all of the plurality of light emitting stacks 522, 524, 526.

Next, FIG. 16 is a plan view of light emitting stacks 522, 524, 526 of another exemplary light emitting unit 520. Referring to FIG. 16, the grooves G of the light emitting stacks 522, 524, 526 may be formed in corner regions in which adjacent side surfaces meet. The grooves G may be formed in a chamfered shape on the corners of the light emitting stacks 522, 524, 526.

The groove G may be formed in each corner region of the light emitting stacks 522, 524, 526 and a corresponding electrode 529a, 529b, 529c or 529d may be disposed within the groove G. One of the electrodes 529a, 529b, 529c, 529d may be a common electrode 529d connected to all of the plurality of light emitting stacks 522, 524, 526.

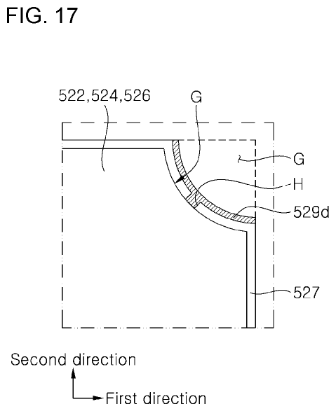

Next, FIG. 17 is a plan view of light emitting stacks 522, 524, 526 of another exemplary light emitting unit 520. Referring to FIG. 17, the grooves G of the light emitting stacks 522, 524, 526 may be formed in corner regions in which adjacent side surfaces meet. The grooves G may be formed in a depressed shape on the corners of the light emitting stacks 522, 524, 526. The inner circumferential surface of the groove G may be a curved surface.

The groove G may be formed in each of the corner regions of the light emitting stacks 522, 524, 526 and a corresponding electrode 529a, 529b, 529c or 529d may be disposed within the groove G. One of the electrodes 529a, 529b, 529c, 529d may be a common electrode 529d connected to all of the plurality of light emitting stacks 522, 524, 526.

The light emitting units 520 described with reference to FIG. 9 to FIG. 17 may also be applied to the light emitting modules 100, 200, 400 according to the first to third embodiments.

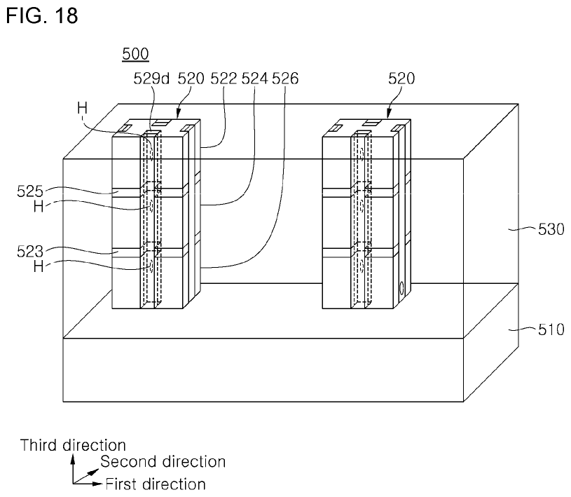

Next, FIG. 18 is a perspective view of the light emitting module 500 shown in FIG. 9. In FIG. 18, the cover layer 527 is not shown. In the light emitting module 500, since the electrode portion 529 is disposed within the grooves G formed on the side surfaces of the light emitting stacks 522, 524, 526, the light emitting units 520 may be miniaturized and the light emitting area of each of the light emitting stacks 522, 524, 526 may be secured as much as possible to maximize the amount of emitted light. Furthermore, since the electrode portion 529 extends vertically along the side surfaces of the light emitting unit 520, the electrode portion 529 may reflect light from the side surfaces of the light emitting unit 520, thereby improving light extraction efficiency and light straightness.

Furthermore, the shape of the grooves G may absorb thermal deformation due to heat generation of the light emitting unit 520 during operation and may trap particles, which may be generated during thermal deformation, thereby improving light emission quality.

Furthermore, referring to FIG. 18, it may be seen that the common electrode 529d of the electrode portion 529 is connected in common to all of first to third light emitting stacks 522, 524, 526 through the openings H formed in the cover layer 527 and disposed at different heights.

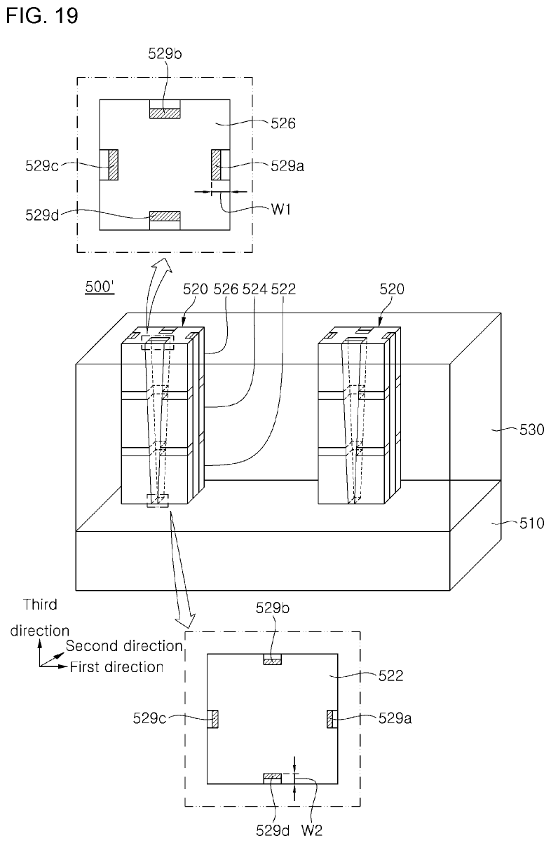

Next, a light emitting module 500′ shown in FIG. 19 is a modification of the light emitting module 500 shown in FIG. 18, and the following description will focus on different features from the light emitting module 500 according to the fourth embodiment described above. The light emitting module 500′ shown in FIG. 19 may have the same or similar configuration to the light emitting module 500 shown in FIG. 18 except that the light emitting units 520 of FIG. 9 and FIG. 10 are replaced with the light emitting units 520 of FIGS. 11 and 12.

In the light emitting unit 520, the widths T1, T2 of the grooves G may be varied depending on the distance from a surface of the substrate 510. In the light emitting unit 520, the depths W1, W2 of the grooves G may be varied depending on the distance from a surface of the substrate 510.

The widths T1, T2 of the grooves G may increase with increasing distance from a surface of the substrate 510. Furthermore, the depths W1, W2 of the grooves G may increase with increasing distance from a surface of the substrate 510. Accordingly, the grooves G may have a maximum width T1 on the upper surface of the light emitting unit 520 and a minimum width T2 on the lower surface of the light emitting unit 520. Accordingly, the inner surfaces S facing each other within the groove G may form inclined surfaces.

A maximum width from an outer boundary of the groove G to one corner of the third light emitting stack 526, a maximum width from the outer boundary of the groove G to one corner of the second light emitting stack 524, and a maximum width from the outer boundary of the groove G to one corner of the first light emitting stack 522 may be different from one another.

The change rate of the width of the groove G may be inversely proportional to the change rate of the width from the outer boundary of the groove G to one corner of the light emitting stacks 522, 524, 526.

In cross-sectional view, the depression areas of the grooves G may increase with increasing distance from a surface of the substrate 510. That is, the areas of the grooves G when viewed from the upper surface of the light emitting unit 520 may be larger than the areas of the grooves G when viewed from the lower side thereof. Accordingly, the first light emitting stack 522 may have a large light emitting area.

However, it should be understood that the disclosed technology is not limited thereto and the depression areas of the grooves G in cross-section thereof may decrease with increasing distance from a surface of the substrate 510.

Further, the plurality of openings H of the cover layer 527 may be disposed within the groove G in which the common electrode 529d is disposed and each of the openings H may be disposed at a different height and formed in a different size.

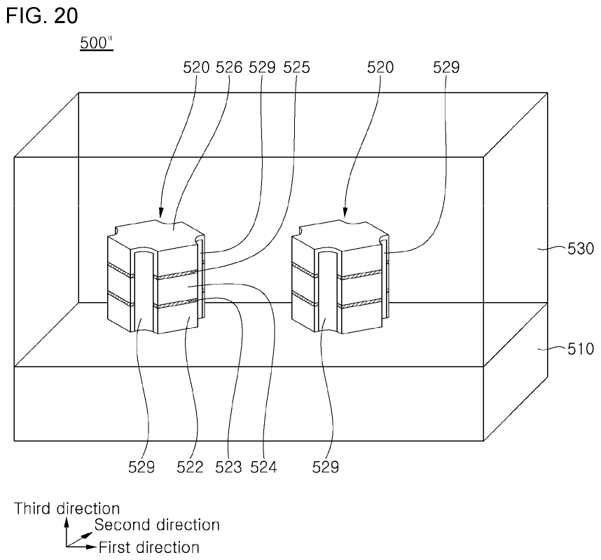

Next, a light emitting module 500″ shown in FIG. 20 is another modification of the light emitting module 500 shown in FIG. 18 and the following description will focus on different features from the light emitting module 500 according to the fourth embodiment described above. The light emitting module 500″ shown in FIG. 20 may have the same or similar configuration to the light emitting module 500 shown in FIG. 18 except that the light emitting unit 520 of FIG. 9 and FIG. 10 is replaced with the light emitting unit 520 of FIG. 17.

The grooves G may be formed at the corners of the light emitting unit 520. That is, each of the grooves G may span at least two adjacent side surfaces of the light emitting unit 520. The grooves G may have a curved inner surface in top view of the light emitting unit 520. Alternatively, the grooves G may have a straight inner surface in top view of the light emitting unit 520.

It should be understood that the depressed regions of the grooves G are not limited to any particular shape, such as a bent shape, a quadrangular shape, a trapezoidal shape, a vertex shape converging to a single vertex, a semi-circular shape, or an arc shape, or others, and may take various other forms.

Although some exemplary embodiments have been described herein with reference to the accompanying drawings, it should be understood that various modifications and changes can be made by those skilled in the art or by a person having ordinary knowledge in the art without departing from the spirit and scope of the invention, as defined by the claims and equivalents thereto.

Therefore, the scope of the invention should be defined by the appended claims and equivalents thereto instead of being limited to the detailed description of the disclosed technology.

### REFERENCE NUMERAL

100, 200, 300, 400, 500: Light emitting module
110, 210, 310, 410, 510: Substrate
120, 220, 320, 420, 520: Light emitting unit
122, 124, 126, 222, 224, 226, 322, 324, 326, 422, 424, 426, 522, 524, 526: Light emitting stack
123, 125, 223, 225, 323, 325, 423, 425, 523, 525: Connection layer
129, 229, 329, 429, 529: Electrode portion
330: 430, 530: Molding member

1. A light emitting module comprising:
a substrate;
at least one light emitting unit disposed on a surface of the substrate; and
a seating guide layer disposed on the surface of the substrate and including an open hole forming a seating region in which the light emitting unit is seated,
wherein a width of the open hole in a first direction is greater than a length of the light emitting unit in the first direction.

2. The light emitting module according to claim 1, wherein a separation distance between the open hole and a side surface of the light emitting unit in the first direction is less than or equal to 0.25 times the length of the light emitting unit in the first direction.

3. The light emitting module according to claim 2, wherein a length of the seating guide layer in the first direction ranges from 2 times to 5 times the separation distance in the first direction.

4. The light emitting module according to claim 1, wherein
in plan view, the light emitting unit has a quadrangular shape having a length in the first direction and a length in a second direction perpendicular to the first direction, and
a diagonal length of the light emitting unit is greater than the width of the open hole of the seating guide layer in the first direction.

5. The light emitting module according to claim 1, wherein
the light emitting unit includes a plurality of light emitting stacks vertically stacked one above another, and
a vertical thickness of a light emitting stack adjacent to the substrate among the plurality of light emitting stacks is greater than a thickness of the seating guide layer.

6. The light emitting module according to claim 1, further comprising:
a bonding layer covering the seating guide layer and the seating region to secure the light emitting unit to the substrate,
wherein a thickness of the bonding layer is less than a thickness of the seating guide layer.

7. The light emitting module according to claim 6, further comprising:
a protective layer disposed on the light emitting unit;
an insulating layer disposed on the protective layer, and
an electrode portion disposed on the insulating layer and connected to the light emitting unit through a first opening formed on the protective layer and a second opening formed on the insulating layer.

8. The light emitting module according to claim 7, wherein the second opening is disposed within the first opening.

9. The light emitting module according to claim 7, wherein
the light emitting unit includes a first light emitting stack, a second light emitting stack, and a third light emitting stack vertically stacked in sequence on the substrate,
each of the first, second, and third light emitting stacks includes a first conductivity type semiconductor layer, a second conductivity type semiconductor layer, and an active layer disposed between the first conductivity type semiconductor layer and the second conductivity type semiconductor layer,
wherein each of the first, second, and third light emitting stacks includes a mesa etching region partially exposing the first conductivity type semiconductor layer, and
the first light emitting stack is formed along a side thereof with a first exposed region in which the first conductivity type semiconductor layer is exposed by the mesa etching region.

10. The light emitting module according to claim 9, wherein
the first opening and the second opening in the first exposed region have an elliptical shape having a long side length and a short side length, and
a direction of the long side length coincides with a longitudinal direction of the first exposed region.

11. The light emitting module according to claim 9, wherein
the first opening and the second opening in the second light emitting stack have an elliptical shape having a long side length and a short side length, and
a direction of the long side length is perpendicular to a longitudinal direction of the first exposed region.

12. The light emitting module according to claim 11, wherein the first opening in the first exposed region has a larger area than the first opening in a second exposed region.

13. The light emitting module according to claim 11, wherein the second opening in the first exposed region has a larger area than the second opening in a second exposed region.

14. The light emitting module according to claim 1, wherein a plurality of light emitting units including the light emitting unit are provided within the seating region.

15. The light emitting module according to claim 1, wherein the light emitting unit includes a plurality of light emitting stacks vertically stacked one above another and an electrode portion disposed in grooves formed on side surfaces of the light emitting stacks.

16. The light emitting module according to claim 1, wherein the light emitting unit further includes a connection layer disposed between adjacent light emitting stacks.

17. The light emitting module according to claim 15, wherein the grooves extend from an upper surface of the light emitting unit to a lower surface thereof.

18. A light emitting module comprising:
a substrate; and
at least one light emitting unit disposed on a surface of the substrate,
wherein the light emitting unit includes:
a plurality of light emitting stacks vertically stacked one above another;
grooves formed on side surfaces of the plurality of light emitting stacks;
a cover layer covering the grooves; and
an electrode portion disposed within the grooves and connected to the light emitting stacks through openings formed on the cover layer.

19. The light emitting module according to claim 18, wherein
the light emitting unit has a polygonal shape including an upper surface, a lower surface, and a plurality of side surfaces, and
the electrode portion includes a plurality of electrodes vertically extending along the side surfaces of the light emitting unit.

20. The light emitting module according to claim 19, wherein
one of the plurality of electrodes is a common electrode connected in common to the plurality of light emitting stacks, and other electrodes of the plurality of electrodes excluding the common electrode are individual electrodes connected to the plurality of light emitting stacks, respectively.
